(19) United States
(12) Patent Application Publication
(10) Pub. No.: US 2017/0257468 A1
(43) Pub. Date: Sep. 7, 2017

(54) APPARATUS AND METHOD FOR TRANSMITTING MOVING PICTURE EXPERTS GROUP (MPEG)-2 TRANSPORT STREAM (TS) BROADCASTING DATA

(71) Applicant: ELECTRONICS AND TELECOMMUNICATIONS RESEARCH INSTITUTE, Daejeon (KR)

(72) Inventors: Joon Young JUNG, Daejeon (KR); Dong Joon CHOI, Daejeon (KR); Nam Ho HUR, Sejong (KR)

(21) Appl. No.: 15/403,616

(22) Filed: Jan. 11, 2017

(30) Foreign Application Priority Data
Mar. 7, 2016 (KR) 10-2016-0026816

(51) Int. Cl. H04L 29/08; H03M 13/09; H03M 13/11; H03M 13/15; H04N 21/854; H04N 21/434

(52) U.S. Cl. CPC H04L 69/324; H04N 21/854; H04N 21/4345; H03M 13/1102; H03M 13/152; H03M 13/09

(57) ABSTRACT

An apparatus and method for transmitting moving picture experts group (MPEG)-2 transport stream (TS) broadcasting data for a broadcasting service based on a physical layer transmission standard defined in a Data over Cable Service Interface Specification (DOCSIS) 3.1. The apparatus includes a converter configured to receive an input of broadcasting data including a plurality of MPEG-2 TS packets and to convert the broadcasting data to a first file with a forward error correction (FEC) codeword structure, and an encoder configured to encode the first file.

### CROSS-REFERENCE TO RELATED APPLICATION

This application claims the benefit of Korean Patent Application No. 10-2016-0026816, filed on Mar. 7, 2016, in the Korean Intellectual Property Office, the disclosure of which is incorporated herein by reference.

### BACKGROUND

1. Field of the Invention

Embodiments relate to a technology of transmitting moving picture experts group (MPEG)-2 transport stream (TS) broadcasting data, and more particularly, to an apparatus and method for transmitting MPEG-2 TS data for a broadcasting service based on a physical layer transmission standard defined in a Data over Cable Service Interface Specification (DOCSIS) 3.1 that is a standard to provide a communication service in a North American cable broadcasting network.

2. Description of the Related Art

A cable broadcasting network may provide a bidirectional communication service in addition to a general broadcasting service, using a cable modem. With development of Data over Cable Service Interface Specifications (DOCSIS), a communication service based on a cable modem has been available. A version of a standard has been repeatedly developed along with a change in a service level required over time.

Generally, the same physical layer transmission standard is used for a broadcasting service and a communication service provided via a cable broadcasting network. In the cable broadcasting network, a physical layer transmission standard includes transmission and reception of radio frequency (RF) signals with a bandwidth of 6 megahertz (MHz) distinguished by frequencies similarly to wireless terrestrial broadcasting.

The same physical layer transmission standard for broadcasting and communication services is applied to a DOCSIS 1.0 through a DOCSIS 3.0. For example, for a transmission of a broadcasting service and a downstream transmission of a communication service, the same quadrature amplitude modulation (QAM) scheme may be used, and a moving picture experts group (MPEG)-2 transport stream (TS) for transmitting broadcasting data may be used as an input interface for modulation. The MPEG-2 TS may be a typical format to transmit digital broadcasting data, and may be commonly used in most digital broadcasting systems. In an example of communication data, a DOCSIS media access control (MAC) frame may be generated and may be changed based on an MPEG-2 TS standard, and the changed DOCSIS MAC frame may be transmitted. To transmit the communication data, an additional process for a change to a physical layer input format is required.

Since a physical layer standard for downstream transmission does not change in the DOCSIS 1.0 through DOCSIS 3.0, the same physical layer standard to transmit digital broadcasting data has been used. However, recently, in a North American cable broadcasting network, a new physical layer standard to transmit communication data is defined in a DOCSIS 3.1 proposed to provide a communication service, and a physical layer input interface format different from an existing DOCSIS is also defined as a DOCSIS MAC frame. Thus, an operation of changing communication data to an MPEG-2 TS which has been required to transmit the communication data may not need to be performed.

Although a physical layer standard of the DOCSIS 3.1 is efficient to transmit communication data, there is a limitation on a transmission of an MPEG-2 TS that is broadcasting data. This is because the DOCSIS 3.1 is a standard for high-speed data transmission based on a broad channel greater than a 24 MHz channel bandwidth, which is distinguished from an existing 6 MHz channel used to provide a broadcasting service. However, recently, with the advent of broadcasting services for transmitting a large amount of broadcasting content (for example, an ultra high definition television (UHDTV)), a transmission using the existing 6 MHz channel often fails. In this example, a transmission of broadcasting data using a broad channel may be very useful. Also, in a physical layer of the DOCSIS 3.1, a large quantity of data may be transmitted within the same bandwidth, due to a high transmission rate in comparison to a physical layer of an existing standard. Thus, a new physical layer standard may be used to more effectively transmit broadcasting data.

### SUMMARY

According to an aspect, there is provided a broadcasting data transmission apparatus for transmitting moving picture experts group (MPEG)-2 transport stream (TS) broadcasting data for a broadcasting service based on a physical layer transmission standard defined in a Data over Cable Service Interface Specification (DOCSIS) 3.1. The broadcasting data transmission apparatus may include a converter configured to receive an input of broadcasting data including a plurality of MPEG-2 TS packets and to convert the broadcasting data to a first file with a forward error correction (FEC) codeword structure, and an encoder configured to encode the first file.

The FEC codeword structure may include at least one of a CW header, an extended header, a payload, a Bose-Chaudhri-Hocquenghem (BCH) parity and a low-density parity-check (LDPC) parity.

The converter may be configured to remove a sync byte from at least one of the plurality of MPEG-2 TS packets included in the broadcasting data, to perform a cyclic redundancy check (CRC) operation and to form a payload of the first file.

The converter may be configured to generate a CW header of the first file so that the CW header includes at least one of a frame pointer field indicating a byte location of a first packet included in a payload of the first file among the plurality of MPEG-2 TS packets, a type field indicating a type of data of the first file, and a valid field indicating whether a value of the frame pointer field is valid.

The converter may be configured to generate an extended header of the first file so that the extended header includes a null packet deletion field indicating whether a null packet is deleted from the plurality of MPEG-2 TS packets, a timestamp field indicating whether a timestamp of a time at which each of the plurality of MPEG-2 TS packets is input is used, and a logical channel number field indicating a number of virtual channels that are logically distinguished.

The encoder may be configured to perform at least one of BCH encoding, LDPC encoding and bit interleaving on the first file.

The broadcasting data transmission apparatus may further include a transmitter configured to transmit the first file using at least one virtual channel.

According to another aspect, there is provided a broadcasting data transmission method of transmitting MPEG-2 TS broadcasting data for a broadcasting service based on a physical layer transmission standard defined in a DOCSIS 3.1. The broadcasting data transmission method may include receiving an input of broadcasting data including a plurality of MPEG-2 TS packets and converting the broadcasting data to a first file with an FEC codeword structure, and encoding the first file.

The FEC codeword structure may include at least one of a CW header, an extended header, a payload, a BCH parity and an LDPC parity.

The converting may include removing a sync byte from at least one of the plurality of MPEG-2 TS packets included in the broadcasting data, performing a CRC operation, and forming a payload of the first file.

The converting may include generating a CW header of the first file so that the CW header includes at least one of a frame pointer field indicating a byte location of a first packet included in a payload of the first file among the plurality of MPEG-2 TS packets, a type field indicating a type of data of the first file, and a valid field indicating whether a value of the frame pointer field is valid.

The converting may include generating an extended header of the first file so that the extended header includes a null packet deletion field indicating whether a null packet is deleted from the plurality of MPEG-2 TS packets, a timestamp field indicating whether a timestamp of a time at which each of the plurality of MPEG-2 TS packets is input is used, and a logical channel number field indicating a number of virtual channels that are logically distinguished.

The encoding may include performing at least one of BCH encoding, LDPC encoding and bit interleaving on the first file.

According to another aspect, there is provided a method of converting a first packet among a plurality of MPEG-2 TS packets included in input broadcasting data to an FEC codeword structure. The method may include removing a sync byte from the first packet, performing a CRC operation and forming a payload, generating a CW header including a byte location of the first packet included in the payload, and performing FEC encoding on the payload and the CW header.

The method may further include generating an extended header including information about whether a null packet is deleted from the first packet and whether a timestamp of a time at which the first packet is input is used.

The performing may include generating a BCH parity by performing BCH encoding on a data block including the payload, the CW header and the extended header, and generating an LDPC parity by performing LDPC encoding on the data block.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a diagram illustrating a physical layer input interface defined in a Data over Cable Service Interface Specification (DOCSIS) 3.1;

FIG. 2 is a block diagram illustrating a broadcasting data transmission apparatus according to an embodiment;

FIG. 3 is a diagram illustrating a forward error correction (FEC) codeword generation process to transmit broadcasting data by a physical layer of the DOCSIS 3.1;

FIG. 4 is a diagram illustrating an FEC codeword generation process when a null packet is deleted and a timestamp is inserted according to an embodiment;

FIG. 5 is a diagram illustrating a timestamp process of an input moving picture experts group (MPEG)-2 transport stream (TS) packet according to an embodiment;

FIG. 6 is a diagram illustrating a basic physical layer downstream transmission structure of the DOCSIS 3.1;

FIG. 7 is a diagram illustrating a physical layer transmission structure for supporting a transmission of a generated FEC codeword according to an embodiment;

FIG. 8 is a diagram illustrating a downstream transmission protocol for a generated FEC codeword according to an embodiment; and

FIG. 9 is a flowchart illustrating a broadcasting data transmission method according to an embodiment.

### DETAILED DESCRIPTION

Particular structural or functional descriptions of embodiments according to the concept of the present disclosure disclosed in the present disclosure are merely intended for the purpose of describing embodiments according to the concept of the present disclosure and the embodiments according to the concept of the present disclosure may be implemented in various forms and should not be construed as being limited to those described in the present disclosure.

Though embodiments according to the concept of the present disclosure may be variously modified and be several embodiments, specific embodiments will be shown in drawings and be explained in detail. However, the embodiments are not meant to be limited, but it is intended that various modifications, equivalents, and alternatives are also covered within the scope of the claims.

Although terms of “first,” “second,” etc. are used to explain various components, the components are not limited to such terms. These terms are used only to distinguish one component from another component. For example, a first component may be referred to as a second component, or similarly, the second component may be referred to as the first component within the scope of the right according to the concept of the present disclosure.

When it is mentioned that one component is “connected” or “accessed” to another component, it may be understood that the one component is directly connected or accessed to another component or that still other component is interposed between the two components. Also, when it is mentioned that one component is “directly connected” or “directly accessed” to another component, it may be understood that no component is interposed therebetween. Expressions used to describe the relationship between components should be interpreted in a like fashion, for example, “between” versus “directly between,” or “adjacent to” versus “directly adjacent to.”

The terminology used herein is for the purpose of describing particular embodiments only and is not intended to be limiting of embodiments. As used herein, the singular forms are intended to include the plural forms as well, unless the context clearly indicates otherwise. It will be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The scope of the right, however, should not be construed as limited to the embodiments set forth herein. Regarding the reference numerals assigned to the elements in the drawings, it should be noted that the same elements will be designated by the same reference numerals.

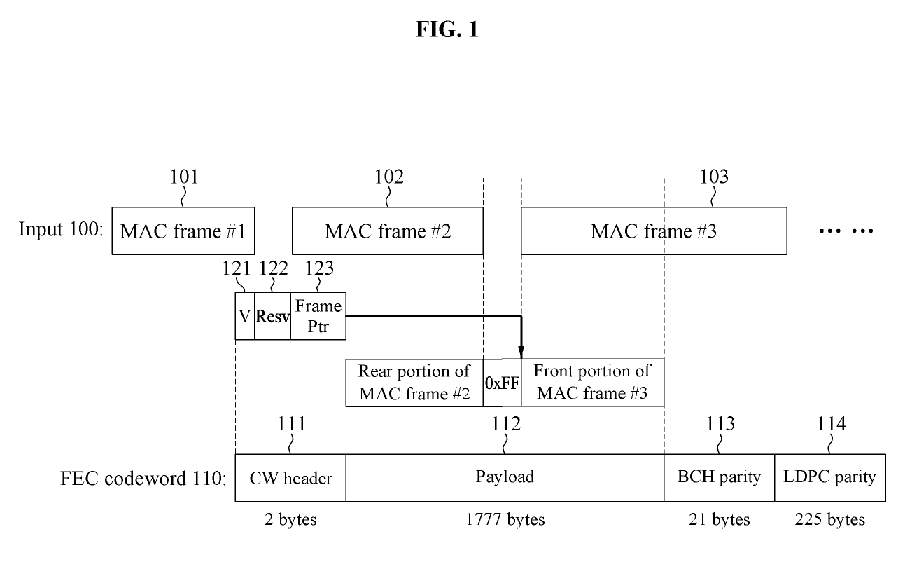

FIG. 1 is a diagram illustrating a physical layer input interface defined in a Data over Cable Service Interface Specification (DOCSIS) 3.1. FIG. 1 illustrates a process of converting a DOCSIS media access control (MAC) frame 100 to a forward error correction (FEC) codeword 110 in response to an input of the DOCSIS MAC frame 100 to a physical layer of the DOCSIS 3.1, to transmit of the DOCSIS MAC frame 100.

Referring to FIG. 1, two consecutive MAC frames may be mapped to an FEC codeword of a predetermined size. For example, a rear portion of a MAC frame #2 102 and a front portion of a MAC frame #3 103 may be located in a payload 112 of the FEC codeword 110. In this example, when data is not input during a predetermined period of time, null bytes with a value of “0xFF” may be selectively filled to have a constant transmission rate.

A frame pointer field 123 of a codeword header 111 indicates a location of a first byte of a new MAC frame that starts in the payload 112. In the present disclosure, a codeword header may be referred to as a “CW header.” A data block of 1,779 bytes obtained by combining the CW header 111 and the payload 112 for FEC encoding may generate a Bose-Chaudhri-Hocquenghem (BCH) parity 113 of 21 bytes and a low-density parity-check (LDPC) parity 114 of 225 bytes through BCH encoding and LDPC encoding, and accordingly a final FEC codeword 110 may be formed. Information included in fields in the CW header 111 may be defined as shown in Table 1 below.

TABLE 1

| Field name | Length | Value |
|---|---|---|
| Valid 121 | 1 bit | ‘0’ = Value of a frame pointer field is not |
| | | valid |
| | | ‘1’ = Value of a frame pointer field is |
| | | valid |
| Reserved 122 | 4 bits | “0000” = Reserved for future use |
| Frame | 11 bits | Indicates a location of a first byte of a |
| Pointer 123 | | DOCSIS MAC frame starting in a payload |

As shown in FIG. 1, a DOCSIS MAC frame is applied as a physical layer input format in the DOCSIS 3.1. A scheme of transmitting data through an upper layer of a DOCSIS MAC layer may be used to transmit moving picture experts group (MPEG)-2 transport streams (TS) that are mainly used in a broadcasting service, however, an efficiency for transmission may decrease.

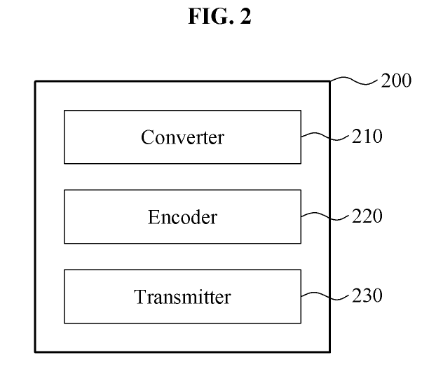

FIG. 2 is a block diagram illustrating a broadcasting data transmission apparatus 200 according to an embodiment.

The broadcasting data transmission apparatus 200 may be configured to transmit MPEG-2 TS broadcasting data for a broadcasting service based on a physical layer transmission standard defined in the DOCSIS 3.1. Referring to FIG. 2, the broadcasting data transmission apparatus 200 may include a converter 210, an encoder 220 and a transmitter 230. However, the transmitter 230 as an optional component may be removed from the broadcasting data transmission apparatus 200.

The converter 210 may receive an input of broadcasting data including a plurality of MPEG-2 TS packets and may convert the broadcasting data to a first file with an FEC codeword structure. The FEC codeword structure may include at least one of a CW header, an extended header, a payload, a BCH parity and an LDPC parity.

The converter 210 may remove a sync byte from at least one of the plurality of MPEG-2 TS packets included in the broadcasting data, may perform a cyclic redundancy check (CRC) operation, and may form a payload of the first file. For example, an 8-bit checksum generated by performing a CRC-8 operation on 187 bytes remaining after a sync byte with a value of “0x47” is removed from the at least one packet may be added to each of the at least one packet, and the at least one packet may be sequentially mapped to the payload.

The converter 210 may generate a CW header of the first file so that the CW header may include at least one of a frame pointer field, a type field and a valid field. The frame pointer field may indicate a byte location of a first packet included in the payload of the first file among the plurality of MPEG-2 TS packets. The type field may indicate a type of data of the first file, and the valid field may indicate whether a value of the frame pointer field is valid.

Also, the converter 210 may generate an extended header of the first file so that the extended header may include a null packet deletion field, a timestamp field and a logical channel number field. The null packet deletion field may indicate whether a null packet is deleted from the plurality of MPEG-2 TS packets. The timestamp field may indicate whether a timestamp of a time at which each of the plurality of MPEG-2 TS packets is input is used. The logical channel number field may indicate a number of virtual channels that are logically distinguished.

The encoder 220 may encode the first file. The encoder 220 may perform at least one of BCH encoding, LDPC encoding and bit interleaving on the first file.

The transmitter 230 may transmit the first file using at least one virtual channel.

The broadcasting data transmission apparatus 200 may effectively transmit MPEG-2 TS broadcasting data based on a physical layer standard defined in the DOCSIS 3.1. Unlike existing DOCSIS, a physical layer input interface format is defined as a DOCSIS MAC frame in the DOCSIS 3.1, and accordingly communication data may be efficiently transmitted based on the physical layer standard. However, there is a limitation on a transmission of an MPEG-2 TS that is broadcasting data. The broadcasting data transmission apparatus 200 may compensate for the above limitation and may enable the MPEG-2 TS to be directly transmitted in a physical layer of the DOCSIS 3.1. Thus, it is possible to enhance a broadcasting data transmission efficiency.

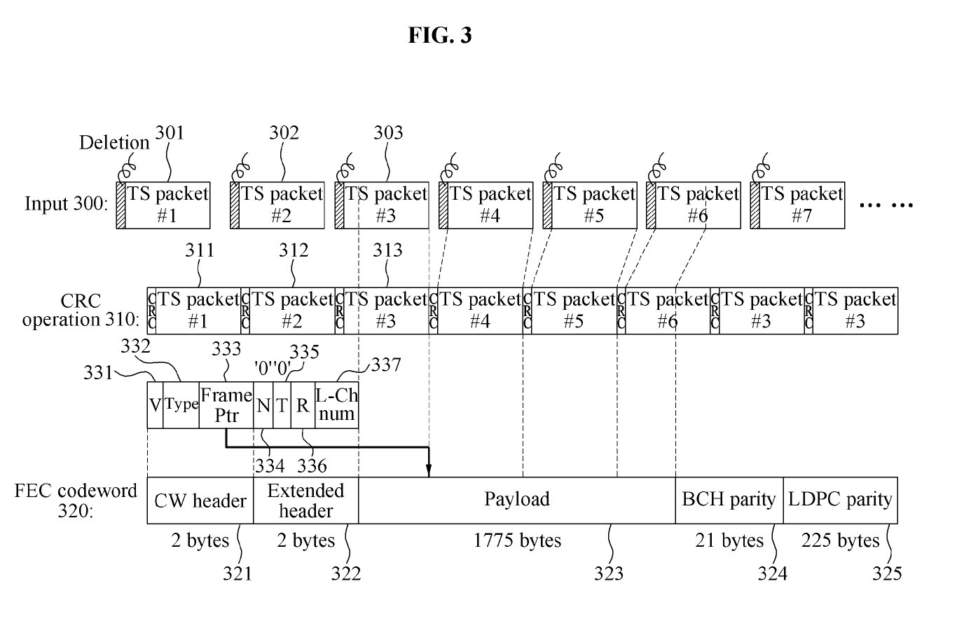

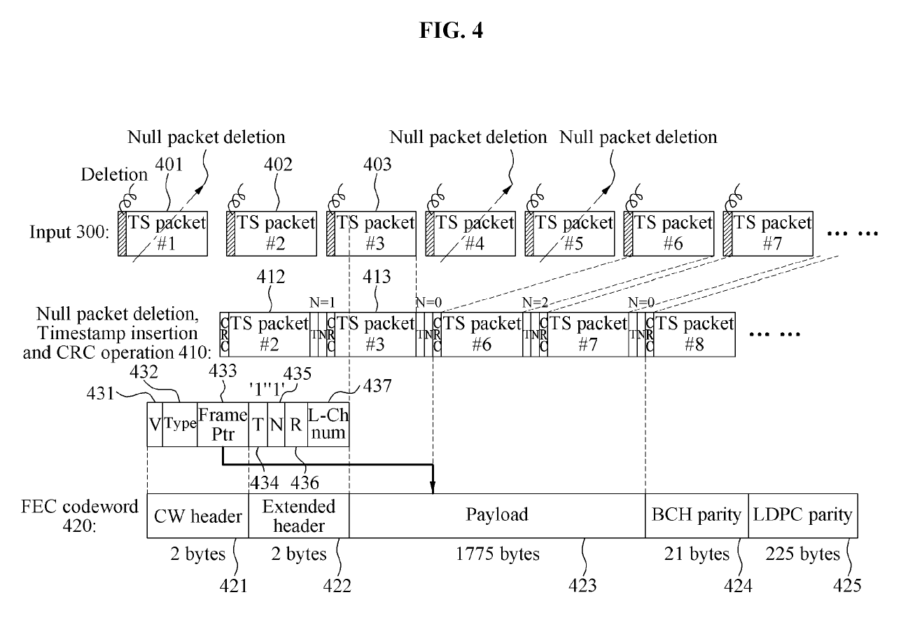

FIG. 3 is a diagram illustrating an FEC codeword generation process to transmit broadcasting data based on a physical layer of the DOCSIS 3.1. FIG. 4 is a diagram illustrating an FEC codeword generation process when a null packet is deleted and a timestamp is inserted according to an embodiment.

An input MPEG-2 TS 300 may include a row of MPEG-2 TS packets, for example, MPEG-2 TS packets 301, 302 and 303, with 188 bytes. An 8-bit checksum generated by performing a CRC-8 operation on 187 bytes remaining after a sync byte with a value of “0x47” is removed from each of the MPEG-2 TS packets may be added to a rear portion of each of MPEG-2 TS packets 311, 312 and 313. The MPEG-2 TS packets 311, 312 and 313 may be sequentially located in a payload 323 of an FEC codeword 320. Also, a portion of the MPEG-2 TS packets may be mapped to a payload of a next FEC codeword. A BCH parity 324 and an LDPC parity 325 of FIG. 3 may be the same as the BCH parity 113 and the LDPC parity 114 of FIG. 1, respectively.

A frame pointer field 333 of a CW header 321 may indicate a location of a first byte of a first MPEG-2 TS packet starting in a payload, and may correspond to a location of a CRC checksum of a previous packet. A reserved field of the CW header 321 may be redefined and used as a type field 332 to identify data to be transmitted. For example, “0001” of the type field 332 may indicate that an MPEG-2 TS is transmitted.

An extended header 322 of 2 bytes may be generated by extending from a rear portion of the CW header 321. Due to the extended header 322, a length of the payload 323 may be 1,775 bytes that is reduced by 2 bytes. The CW header 321 and the extended header 322 generated as described above may be defined as shown in Table 2 below.

TABLE 2

| Classification | Field name | Length | Value |
|---|---|---|---|
| CW | Valid 331 | 1 bit | ‘0’ = Value of a frame pointer |
| header 321 | | | field is not valid |
| (2 bytes) | | | ‘1’ = Value of a frame pointer |
| | | | field is valid |
| | Type 332 | 4 bits | “0000” = Transmission of |
| | | | DOCSIS MAC frame |
| | | | “0001” = Transmission of |
| | | | MPEG-2 TS |
| | | | “0010”~“1111” = Reserved for |
| | | | future use |
| | Frame | 11 bits | Indicates a location of a first |
| | pointer 333 | | byte of a DOCSIS MAC |
| | | | frame starting in a payload |
| Extended | Null packet | 1 bit | ‘0’ = Null packet deletion is |
| header 322 | deletion 334 | | not used |
| (2 bytes) | | | ‘1’ = Null packet deletion is |
| | | | used |
| | Timestamp | 1 bit | ‘0’ = Timestamp is not used |
| | 335 | | ‘1’ = Timestamp is used |
| | Reserved | 2 bits | Reserved for future use |
| | 336 | | |
| | Logical | 12 bits | Indicates channels that are |
| | channel | | logically distinguished from |
| | number 337 | | each other (the channels are |
| | | | the same as a virtual channel |
| | | | used in digital broadcasting) |

A null packet deletion field 334 defined in the extended header 322 may indicate whether a null TS packet is removed from input MPEG-2 TS packets. A timestamp field 335 defined in the extended header 322 may indicate whether information on a time at which an MPEG-2 TS packet is input is added to a packet. The FEC codeword 320 may indicate that a null packet is not deleted and a timestamp is not added, because both the null packet deletion field 334 and the timestamp field 335 have a value of zero. An FEC codeword 420 of FIG. 4 may indicate that a null packet is deleted and a timestamp is used.

Referring to FIG. 4, null packet deletion, timestamp insertion and a CRC operation may be performed with respect to 187 bytes remaining after a sync byte with a value of “0x 47” is removed from each of input MPEG-2 TS packets, for example, MPEG-2 TS packets 401, 402 and 403, in operation 410. An “N” field, a “T” field and a checksum generated by performing the null packet deletion, the timestamp insertion and the CRC operation may be added to a rear portion of each of MPEG-2 TS packets 412 and 413 and the MPEG-2 TS packets 412 and 413 may be sequentially located in a payload 423 of the FEC codeword 420.

Generally, an MPEG-2 TS may include a meaningless null packet to maintain a transmission rate over a predetermined level. To increase an efficiency for transmission, a meaningless packet may not be transmitted. However, since a predetermined transmission rate needs to be maintained in the MPEG-2 TS, a null packet may be included in the MPEG-2 TS and may be transmitted. For example, when a null packet is deleted in a transmitter, a receiver may need to generate the deleted packet again. Accordingly, information about whether a null packet is deleted may be provided based on the null packet deletion field 334 and a null packet deletion field 435 of an extended header 422. Also, an “N” field with a length of 1 byte may be added to a rear portion of each of the MPEG-2 TS packets 412 and 413 that are additionally transmitted, and may indicate a number of null packets deleted from a front portion of a corresponding packet.

In addition, since a predetermined transmission rate of an MPEG-2 TS needs to be maintained, a predetermined time interval between packets included in the MPEG-2 TS may need to be maintained. Since the MPEG-2 TS includes packets to transfer information associated with time for playback of video and audio, it may be difficult to play back video and audio when jitter occurs in a transmission time of packets during transmission. To solve the above problem, the timestamp field 335 and a timestamp field 434 of the extended header 422 may be used to notify whether a timestamp of each packet is used, and a “T” field with a length of 3 bytes may be added to a rear portion of each of the MPEG-2 TS packets 412 and 413 and may indicate a time at which a corresponding packet is input.

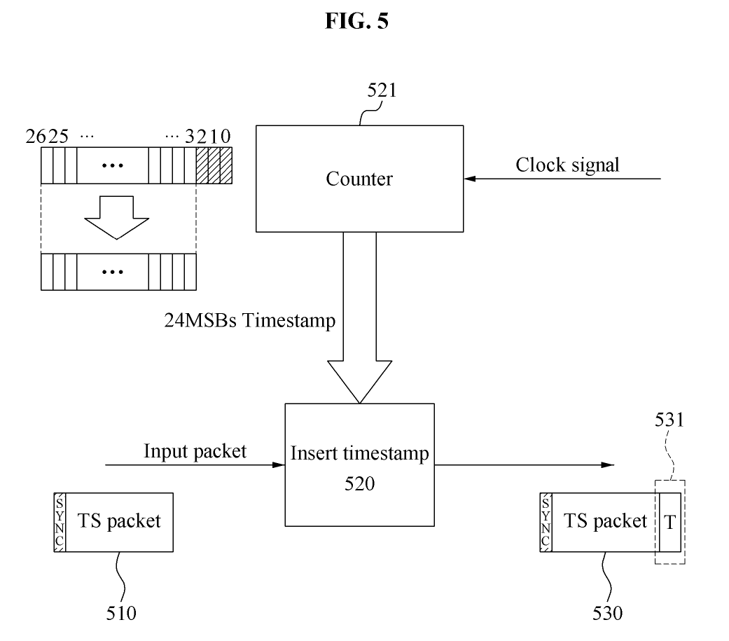

Null packet deletion and use of a timestamp may be selectively performed in examples of FIGS. 3 and 4, however, use of a timestamp may be recommended in transmission of an MPEG-2 TS. For example, when a null packet deletion is accepted, a timestamp may need to be used. A process of using a timestamp for an MPEG-2 TS packet will be further described with reference to FIG. 5.

Logical channel number fields 337 and 437 included in the extended headers 322 and 422, respectively, may indicate a number of channels that are logically distinguished, and the logical channels may be understood to be the same as a virtual channel used in digital broadcasting. Since the DOCSIS 3.1 is a standard based on transmission of a large quantity of data using a broad channel, it is possible to provide a large number of video services in a single broad channel. In an existing transmission system using 6 megahertz (MHz) as a single broadcasting channel, about five or six video services may be multiplexed and provided by distinguishing virtual channels. Since the multiplexing may be performed in an MPEG-2 TS layer, there is no relevance to a physical layer of transmission. In the present disclosure, services may be classified in a physical layer so that a large number of video services may be distinguished within a single broad channel, and accordingly the logical channel number fields 337 and 437 may be defined.

A BCH parity 424 and an LDPC parity 425 of FIG. 4 may be the same as the BCH parity 113 and the LDPC parity 114 of FIG. 1, respectively.

FIG. 5 is a diagram illustrating a timestamp process of an input MPEG-2 TS packet according to an embodiment.

Referring to FIG. 5, when a TS packet 510 is input, a timestamp may be acquired using a counter 521 synchronized by a sampling clock signal. The timestamp may be a 24-bit counter generated using 25.6 MHz. In the DOCSIS 3.1, a sampling clock to generate an orthogonal frequency-division multiplexing (OFDM) modulation signal is defined as 204.8 MHz. By multiplication of the sampling clock of 204.8 MHz by ⅛, a value of 25.6 MHz may be acquired.

When a timestamp is used, a timestamp for the input TS packet 510 may be inserted in operation 520, a “T” field 531 of 3 bytes may be added to a rear portion of a TS packet 530, and may indicate a time at which a corresponding packet is input.

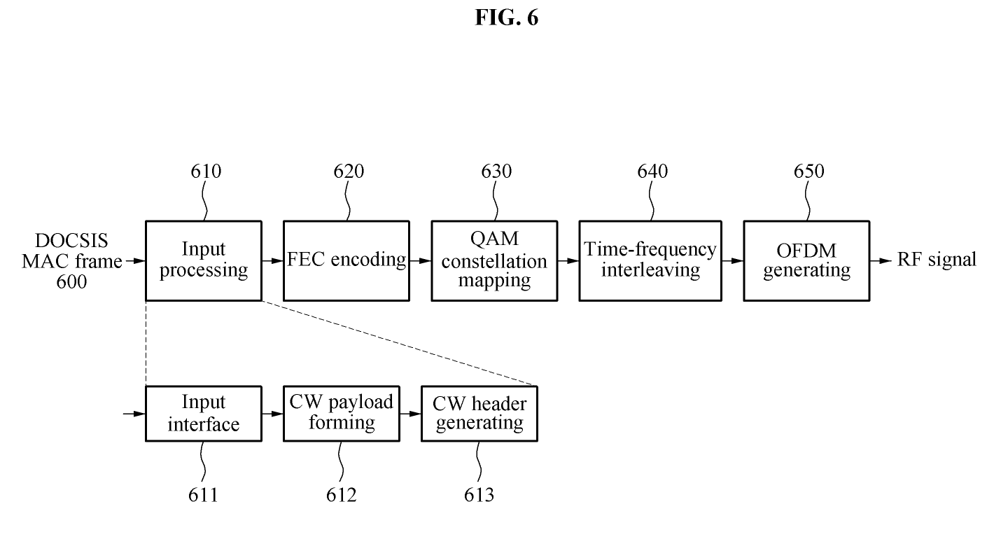

FIG. 6 is a diagram illustrating a basic physical layer downstream transmission structure of the DOCSIS 3.1.

Referring to FIG. 6, the basic physical layer downstream transmission structure of the DOCSIS 3.1 may include an input processing block 610, an FEC encoding block 620, a quadrature amplitude modulation (QAM) constellation mapping block 630, a time-frequency interleaving block 640, and an OFDM signal generating block 650. The input processing block 610 may receive a DOCSIS MAC frame 600 generated in a DOCSIS MAC layer. The FEC encoding block 620 may perform BCH encoding, LDPC encoding and bit interleaving.

The input processing block 610 may include an input interface sub-block 611, a CW payload forming sub-block 612 and a CW header generating sub-block 613. The input processing block 610 may be used to process a codeword conversion process of a MAC frame described above with reference to FIG. 1.

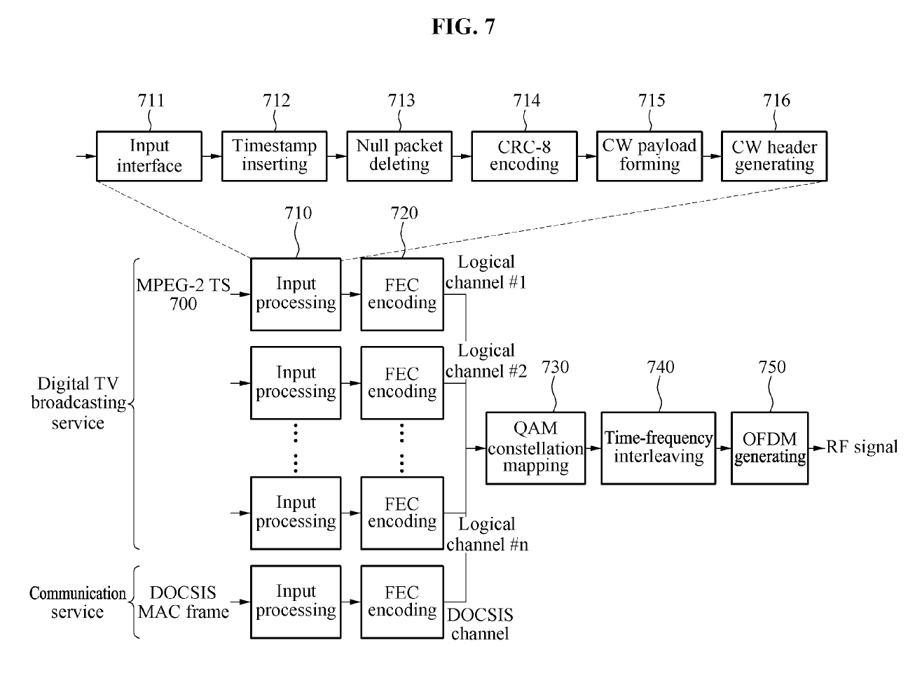

FIG. 7 is a diagram illustrating a physical layer transmission structure for supporting a transmission of a generated FEC codeword according to an embodiment.

In the physical layer transmission structure of FIG. 7, an input processing block 710 and an FEC encoding block 720 may be configured using a single logical channel. For a broadcasting service, the input processing block 710 may process an input of an MPEG-2 TS 700 and the FEC encoding block 720 may perform FEC encoding. Since a logical channel number field is included in an extended header of an FEC codeword converted from an MPEG-2 TS packet, channels may be distinguished for each codeword.

Also, in the physical layer transmission structure of FIG. 7, a DOCSIS MAC frame may be transmitted in addition to broadcasting data of an MPEG-2 TS, because the DOCSIS MAC frame may be distinguished from the MPEG-2 TS by changing a reserved field of 4 bits defined in a CW header and using the reserved field as a type field in the DOCSIS 3.1. Also, the input processing block 710 may additionally include a timestamp inserting sub-block 712, a null packet deleting sub-block 713 and a CRC-8 encoding sub-block 714 for transmission of the MPEG-2 TS, in comparison to an existing structure for supporting a transmission of a DOCSIS MAC frame. The input processing block 710 may be used to process a codeword mapping process for an MPEG-2 TS described above with reference to FIGS. 3 and 4.

When the FEC encoding is performed, the DOCSIS MAC frame may be processed by a QAM constellation mapping block 730, a time-frequency interleaving block 740, and an OFDM signal generating block 750, and the processed DOCSIS MAC frame may be transmitted, similarly to the basic physical layer downstream transmission structure of FIG. 6.

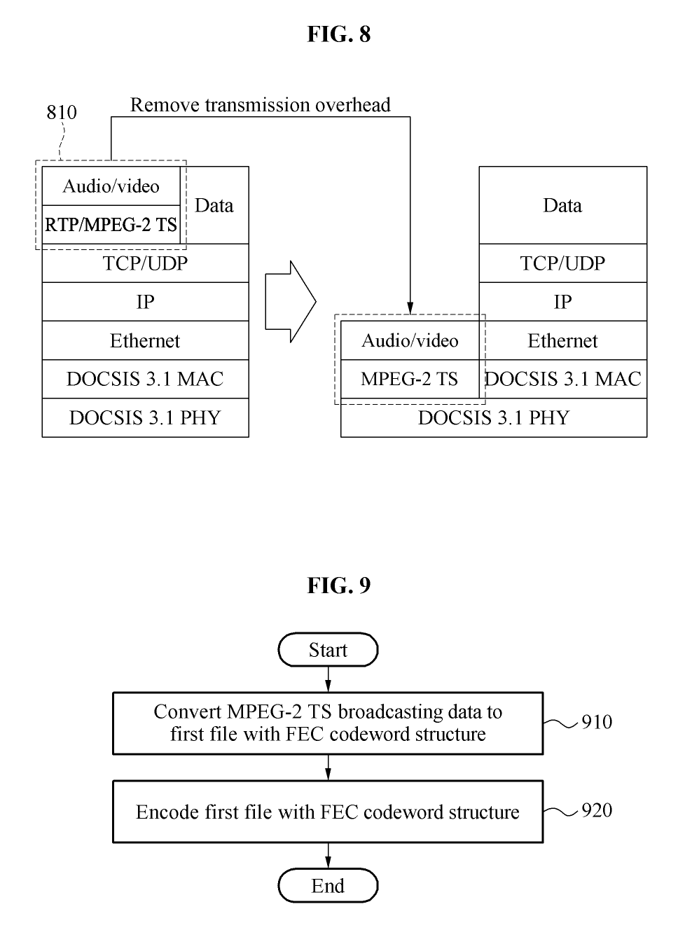

FIG. 8 is a diagram illustrating a downstream transmission protocol for a generated FEC codeword according to an embodiment.

In FIG. 8, audio/video data 810 may be transferred by an application layer (for example, an open systems interconnection (OSI) layer 7) to provide a broadcasting service in the DOCSIS 3.1. When a generated FEC codeword according to an embodiment is used, audio/video data may be transmitted by a network layer (for example, an OSI layer 3). Thus, broadcasting service data may be transmitted directly instead of passing through an intermediate layer. Also, a transmission overhead for corresponding layers may not be added, and thus a transmission efficiency may be further enhanced.

FIG. 9 is a flowchart illustrating a broadcasting data transmission method according to an embodiment.

The broadcasting data transmission method may be performed by a broadcasting data transmission apparatus to transmit MPEG-2 TS broadcasting data for a broadcasting service based on a physical layer transmission standard defined in the DOCSIS 3.1.

In operation 910, a converter of the broadcasting data transmission apparatus may receive an input of broadcasting data including a plurality of MPEG-2 TS packets and may convert the broadcasting data to a first file with an FEC codeword structure. The FEC codeword structure may include at least one of a CW header, an extended header, a payload, a BCH parity and an LDPC parity.

In operation 910, the converter may remove a sync byte from at least one of the plurality of MPEG-2 TS packets included in the broadcasting data, may perform a cyclic redundancy check (CRC) operation, and may form a payload of the first file. For example, an 8-bit checksum generated by performing a CRC-8 operation on 187 bytes remaining after a sync byte with a value of “0x47” is removed from the at least one packet may be added to each of the at least one packet, and the at least one packet may be sequentially mapped to the payload.

In operation 910, the converter may generate a CW header of the first file so that the CW header may include at least one of a frame pointer field, a type field and a valid field. The frame pointer field may indicate a byte location of a first packet included in the payload of the first file among the plurality of MPEG-2 TS packets. The type field may indicate a type of data of the first file, and the valid field may indicate whether a value of the frame pointer field is valid. Also, the converter may generate an extended header of the first file so that the extended header may include a null packet deletion field, a timestamp field and a logical channel number field. The null packet deletion field may indicate whether a null packet is deleted from the plurality of MPEG-2 TS packets. The timestamp field may indicate whether a timestamp of a time at which each of the plurality of MPEG-2 TS packets is input is used. The logical channel number field may indicate a number of virtual channels that are logically distinguished.

In operation 920, an encoder of the broadcasting data transmission apparatus may encode the first file obtained in operation 910. In operation 920, the encoder may perform at least one of BCH encoding, LDPC encoding and bit interleaving on the first file.

When operation 920 is performed, a transmitter of the broadcasting data transmission apparatus may transmit the first file using at least one virtual channel.

The units and/or modules described herein may be implemented using hardware components and software components. For example, the hardware components may include microphones, amplifiers, band pass filters, audio to digital convertors, and processing devices. A processing device may be implemented using one or more hardware device configured to carry out and/or execute program code by performing arithmetical, logical, and input/output operations. The processing device(s) may include a processor, a controller and an arithmetic logic unit, a digital signal processor, a microcomputer, a field programmable gate array, a programmable logic unit, a microprocessor or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will appreciated that a processing device may include multiple processing elements and multiple types of processing elements. For example, a processing device may include multiple processors or a processor and a controller. In addition, different processing configurations are possible, such as parallel processors.

The software may include a computer program, a piece of code, an instruction, or some combination thereof, to independently or collectively instruct and/or configure the processing device to operate as desired, thereby transforming the processing device into a special purpose processor. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums.

The methods according to the above-described embodiments may be recorded in non-transitory computer-readable media including program instructions to implement various operations of the above-described embodiments. The media may also include, alone or in combination with the program instructions, data files, data structures, and the like. The program instructions recorded on the media may be those specially designed and constructed for the purposes of embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher level code that may be executed by the computer using an interpreter. The above-described devices may be configured to act as one or more software modules in order to perform the operations of the above-described embodiments, or vice versa.

A number of embodiments have been described above. Nevertheless, it should be understood that various modifications may be made to these embodiments. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claim.

What is claimed is:

1. A broadcasting data transmission apparatus comprising:
a converter configured to receive an input of broadcasting data comprising a plurality of moving picture experts group (MPEG)-2 transport stream (TS) packets and to convert the broadcasting data to a first file with a forward error correction (FEC) codeword structure; and
an encoder configured to encode the first file.

2. The broadcasting data transmission apparatus of claim 1, wherein the FEC codeword structure comprises at least one of a CW header, an extended header, a payload, a Bose-Chaudhri-Hocquenghem (BCH) parity and a low-density parity-check (LDPC) parity.

3. The broadcasting data transmission apparatus of claim 1, wherein the converter is configured to remove a sync byte from at least one of the plurality of MPEG-2 TS packets included in the broadcasting data, to perform a cyclic redundancy check (CRC) operation and to form a payload of the first file.

4. The broadcasting data transmission apparatus of claim 1, wherein the converter is configured to generate a CW header of the first file so that the CW header includes at least one of a frame pointer field indicating a byte location of a first packet included in a payload of the first file among the plurality of MPEG-2 TS packets, a type field indicating a type of data of the first file, and a valid field indicating whether a value of the frame pointer field is valid.

5. The broadcasting data transmission apparatus of claim 1, wherein the converter is configured to generate an extended header of the first file so that the extended header includes a null packet deletion field indicating whether a null packet is deleted from the plurality of MPEG-2 TS packets, a timestamp field indicating whether a timestamp of a time at which each of the plurality of MPEG-2 TS packets is input is used, and a logical channel number field indicating a number of virtual channels that are logically distinguished.

6. The broadcasting data transmission apparatus of claim 1, wherein the encoder is configured to perform at least one of BCH encoding, LDPC encoding and bit interleaving on the first file.

7. The broadcasting data transmission apparatus of claim 1, further comprising:
a transmitter configured to transmit the first file using at least one virtual channel.

8. A broadcasting data transmission method comprising:
receiving an input of broadcasting data comprising a plurality of moving picture experts group (MPEG)-2 transport stream (TS) packets and converting the broadcasting data to a first file with a forward error correction (FEC) codeword structure; and
encoding the first file.

9. The broadcasting data transmission method of claim 8, wherein the FEC codeword structure comprises at least one of a CW header, an extended header, a payload, a Bose-Chaudhri-Hocquenghem (BCH) parity and a low-density parity-check (LDPC) parity.

10. The broadcasting data transmission method of claim 8, wherein the converting comprises removing a sync byte from at least one of the plurality of MPEG-2 TS packets included in the broadcasting data, performing a cyclic redundancy check (CRC) operation, and forming a payload of the first file.

11. The broadcasting data transmission method of claim 8, wherein the converting comprises generating a CW header of the first file so that the CW header includes at least one of a frame pointer field indicating a byte location of a first packet included in a payload of the first file among the plurality of MPEG-2 TS packets, a type field indicating a type of data of the first file, and a valid field indicating whether a value of the frame pointer field is valid.

12. The broadcasting data transmission method of claim 8, wherein the converting comprises generating an extended header of the first file so that the extended header includes a null packet deletion field indicating whether a null packet is deleted from the plurality of MPEG-2 TS packets, a timestamp field indicating whether a timestamp of a time at which each of the plurality of MPEG-2 TS packets is input is used, and a logical channel number field indicating a number of virtual channels that are logically distinguished.

13. The broadcasting data transmission method of claim 8, wherein the encoding comprises performing at least one of BCH encoding, LDPC encoding and bit interleaving on the first file.

14. A method of converting a first packet among a plurality of moving picture experts group (MPEG)-2 transport stream (TS) packets included in input broadcasting data to a forward error correction (FEC) codeword structure, the method comprising:
removing a sync byte from the first packet, performing a cyclic redundancy check (CRC) operation and forming a payload;
generating a CW header comprising a byte location of the first packet included in the payload; and
performing FEC encoding on the payload and the CW header.

15. The method of claim 14, further comprising:
generating an extended header comprising information about whether a null packet is deleted from the first packet and whether a timestamp of a time at which the first packet is input is used.

16. The method of claim 15, wherein the performing comprises:
generating a Bose-Chaudhri-Hocquenghem (BCH) parity by performing BCH encoding on a data block comprising the payload, the CW header and the extended header; and
generating a low-density parity-check (LDPC) parity by performing LDPC encoding on the data block.
